(19) United States
(12) Patent Application Publication
(10) Pub. No.: US 2025/0364215 A1
(43) Pub. Date: Nov. 27, 2025

(54) System and Method for Delivering Radio Frequency Power to a Chamber with Multiple Plasma States

(71) Applicant: Yang Pan, Singapore (SG)

(72) Inventor: Yang Pan, Singapore (SG)

(73) Assignee: Inspiring Atoms, Pte Ltd, Singapore (SG)

(21) Appl. No.: 18/672,264

(22) Filed: May 23, 2024

(51) Int. Cl. H01J 37/32; H03F 3/24

(52) U.S. Cl. CPC H01J 37/32183; H03F 3/245; H03F 2200/451

(57) ABSTRACT

This disclosure relates to an advanced process system for semiconductor manufacturing that utilizes direct frequency generation in radio frequency (RF) power generators to establish optimal operating frequencies. By pre-determining resonating frequencies for different processing steps, the system eliminates the necessity for traditional proportional-integral-derivative (PID) control loops, allowing swift transitions between processing steps. This approach enhances both system stability and efficiency in semiconductor manufacturing processes.

### BACKGROUND OF THE INVENTION

### 1. Field of the Invention

The present invention relates to process systems for semiconductor manufacturing, specifically to methods and systems for efficiently determining and adjusting the resonating frequency in radio frequency (RF) power generators used in such systems. The invention is particularly pertinent to achieving optimal plasma conditions in chambers during semiconductor manufacturing.

### 2. Description of the Prior Art

In the semiconductor manufacturing industry, process systems utilizing of plasma play a pivotal role in various stages of substrate production. These systems include chambers conducive to the vacuum environments required for semiconductor manufacturing processes such as substrate etching. A key component in these chambers is the RF power generator, which produces plasma comprising species like electrons, ions, and neutrals.

As critical dimensions (CD) on substrates have continuously shrunk to the nanometer range and the aspect ratio of structures being etched approaches one hundred, precise control of the energy and angular distributions of ions has become crucial. Various patents have addressed improving ion energy distribution with low angular spread, including U.S. Pat. No. 10,141,163 to Lill et al., U.S. Pat. No. 10,755,895 to Marakhtanov et al., and U.S. Pat. No. 11,915,912 to Shoeb et al. Additionally, pulsing techniques for better control of ions in the plasma have been disclosed in patents such as U.S. Pat. No. 8,692,467 to Benjamin et al., U.S. Pat. No. 8,962,488 to Liao et al., and U.S. Pat. No. 9,171,700 to Gilmore et al. These techniques have led to multiple plasma states, necessitating complex control schemes to maintain RF circuitry resonance for different plasma states within the chamber.

Various control techniques have been explored, as seen in patents like U.S. Pat. No. 8,736,377 to Rughoonundon et al., U.S. Pat. No. 9,390,893 to Valcore, Jr. et al., U.S. Pat. No. 9,595,423 to Leray et al., U.S. Pat. No. 9,872,373 to Shimizu et al., and U.S. Pat. No. 10,256,077 to Valcore, Jr. et al. Additionally, specific techniques for matching units for RF power generators delivering multiple frequencies and power levels are disclosed in patents such as U.S. Pat. No. 9,059,678 to Long et al., U.S. Pat. No. 9,401,264 to Marakhtanov et al., U.S. Pat. No. 9,984,859 to Marakhtanov et al., U.S. Pat. No. 10,403,482 to Howald et al., U.S. Pat. No. 10,984,985 to Mavretic, U.S. Pat. No. 11,224,116 to Long et al., and U.S. Pat. Pub. No. 2022/0216038 by Wu et al.

Matchless plasma sources have been developed to improve response time of impedance matching without involving mechanically movable parts, as disclosed in U.S. Pat. No. 11,716,059 to Raymond et al., U.S. Pat. No. 10,847,345 to Long et al., U.S. Pat. No. 11,224,116 to Long et al., and U.S. Pat. Pub. No. 2021/0210314 by Wang et al.

The optimal performance of an RF power generator is contingent upon its ability to operate at the correct resonating frequency. Traditional methods of determining this frequency rely on monitoring performance indicators like reflected power from the chamber and adjusting the RF power generator's frequency accordingly. To speed up the frequency adjustment, control mechanisms such as proportional-integral-derivative (PID) controls and phase-locked loops (PLL) have been employed. However, these methods often require a setting time range from several milliseconds to several dozen milliseconds to ensure the resonator achieves its resonating state, which can be a limiting factor in semiconductor processing, especially when faster pulsing schemes are in use. Moreover, pushing these control mechanisms to their speed limits can lead to stability issues with the RF power generator, potentially jeopardizing the quality of the semiconductor manufacturing process.

With the semiconductor industry's incessant pursuit of increased efficiency and precision, there is a pressing need for methods and systems that can quickly and accurately determine the correct resonating frequency for RF power generators. Ideally, these methods would ensure that the resonator swiftly reaches its resonating state without compromising the stability of the RF power generator.

### SUMMARY

The present disclosure describes innovations related to process systems for semiconductor manufacturing, specifically focusing on swiftly determining the resonating frequency in RF power generators. Within the semiconductor processing context, this resonating frequency is integral to achieving optimal plasma conditions in a chamber conducting plasma-based processing.

In prior art, as discussed earlier, the RF power generator's frequency is exemplarily adjusted by monitoring the power reflected from the processing chamber. If this power surpasses a set threshold, a new operating frequency is generated by the RF controller. To hasten this frequency adjustment, a PID control is used. In other designs, phase differences are measured using a PLL to compare against a benchmark for achieving the desired performance. However, the traditional use of PID control can be sluggish, taking several milliseconds to several dozen milliseconds to adjust, leading to potential stability concerns in the RF power generator.

A novel process system has been introduced and elaborated with various embodiments, encompassing components like a chamber body, a plasma source, and a chuck for supporting a substrate. Notably, in this process system, the RF power generator's operating frequency is directly provided by a system controller, eliminating the need for extended tuning procedures based on feedback loops. This change ensures that the resonator reaches its resonating state in several microseconds or less, offering a significant efficiency boost.

A significant feature of the system controller is its dual engines: a training engine and an inference engine. The training engine's role is to determine the resonating frequencies aligned with different steps in a process recipe. In some implementations, a frequency scan is conducted for several frequencies within a predetermined range. A performance indicator is measured as a function of the frequency. Based on the measurement results, the resonating frequency can be determined.

In one example, the performance indicator is the reflected power from the chamber measured at an output of the resonator by a sensor.

In one implementation, the resonating frequency can be decided based on measured data using an interpolating or an extrapolating algorithm to identify the frequency with the best performance indicator. In another implementation, a neural network may be constructed and trained based on measured performance indicators as a function of the frequency. The resonating frequency can then be decided based on the neural network. When the neural network is employed, more factors affecting the resonating frequency can be incorporated.

The predetermined frequency range should adequately cover the resonating frequency. The frequency scan should be applied to each of the plasma states stipulated by the process recipe.

Once identified, these resonating frequencies are stored in a training database. Later, when the system is engaged in processing a substrate, it references this training database using the inference engine to determine the appropriate resonating frequency.

In some implementations, an outlined inference process is set to determine the resonating frequency for each step of the substrate's manufacturing process. It involves executing the manufacturing steps using the previously identified resonating frequencies to maintain ideal plasma conditions without additional tuning to achieve desired operating frequencies.

Finally, in the production phase, the system controller continuously measures performance indicators for each processing step. These measurements are methodically recorded and monitored over time. To ensure the consistency and reliability of the process, a statistical process control (SPC) methodology is applied. If the indicators deviate from set parameters, the system controller triggers a re-training event for the RF generator to recalibrate and ensure optimal performance.

### BRIEF DESCRIPTIONS OF DRAWINGS

For enhanced clarity, the following description refers to accompanying drawings:

FIG. 1: Depicts an exemplary process system equipped with a conventional RF power generator.

FIG. 2: Presents a functional diagram of a chamber paired with an RF power generator. This generator operates using direct resonating frequency generation sourced from a training database.

FIG. 3: Illustrates a flowchart of the exemplary RF power generator when functioning in its training mode.

FIG. 4: Displays a flowchart of the exemplary RF power generator while operating in its inference mode.

FIG. 5: Highlights a flowchart of the exemplary process system in its production operation.

### DETAILED DESCRIPTIONS

To ensure comprehensive understanding, this section delves into detailed embodiments of the present invention. Although certain specifics are provided for clarity, modifications and variations that align with the subsequent claims are deemed appropriate. Conventional methods and components are highlighted to underscore the distinct features of the invention.

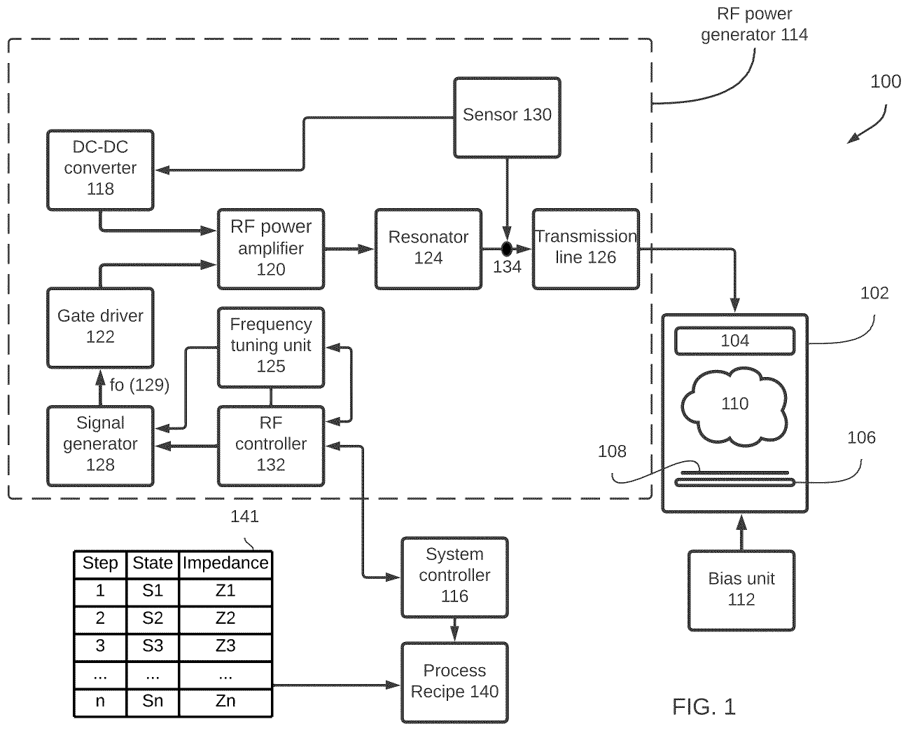

FIG. 1 presents a conventional process system (100) which incorporates a chamber (102). Inside or in the proximity of the chamber (102), there exists a plasma source (104) connected to an RF power generator (114). This chamber (102) establishes a vacuum environment suitable for various processing tasks. While not depicted, process gases or precursors are introduced into the chamber through a specific delivery unit. Similarly, reaction byproducts are expelled using a vacuum pump. The plasma source (104) can have different configurations based on the intended application. For instance, the plasma source (104) can be either an inductively coupled plasma (ICP) or a transformer coupled plasma (TCP). These sources, ICP or TCP, are generally positioned adjacent to, but isolated from, the chamber (102), often through a window. In such setups, RF power is directed to a coil, creating an electromagnetic field inside the chamber (102). Gases within the chamber are then ignited to produce a plasma (110) comprising electrons, ions, and neutrals, which is a prerequisite for processes like etching a substrate (108) held by a chuck (106). A bias unit (112) is employed to boost ion energy in the plasma (110) and its associated sheath. This bias unit (112) could be an RF power generator attached to the chuck (106) or might take the form of a tailored waveform generator.

In other scenarios, capacitively coupled plasma (CCP) is utilized. In these cases, both 104 and 106 serve as electrodes for the capacitor, accepting RF power from either the top or bottom. For this disclosure, the ICP source combined with the bias unit (112) serves as the primary example to elucidate the inventive concept across varied embodiments without constraining the scope of the invention.

The RF power generator (114) also integrates an RF power amplifier (120). Such amplifiers, like the class E power amplifier, could have many different implementations as known in the art. The amplifier's (120) output is coupled to the source (104) through a resonator (124) and a transmission line (126). In many instances, the resonator (124) is an RF matching circuit comprising elements like inductors, capacitors, and resistors. In certain designs, the associated capacitance of the capacitors can be adjusted mechanically. In other designs, the adjustment is achieved electronically. The resonator (124) ensures the output impedance of the amplifier (120) matches the load impedance introduced by the chamber (102) when the plasma (110) is ignited. The transmission line (126) could be an important part of the impedance matching, which must be taken into consideration together with the load impedance created by the chamber (102). It is important that the combined impedance of resonator (124), transmission line (126), and chamber (102) corresponds with the amplifier's (120) output impedance.

A DC-DC converter (118) is connected to the amplifier (120), modulating the DC power it receives. Additionally, a gate driver (122), interfacing with the gate of power MOSFETs of the amplifier, uses a resonating circuit to minimize power consumption. The operating frequency of the amplifier (120), denoted as fo (129), is determined by a signal generator (128) that's linked to the gate driver (122), and this frequency resonates with that of the resonator (124).

A state-of-the-art process recipe (140) for the process system (102) can encompass several steps: 1 to n, as portrayed in table (141). Each step might be defined by distinct plasma states S1 to Sn with corresponding impedances Z1 to Zn. Therefore, the resonating frequency of the resonator (124) could vary for each step due to alterations in the load impedance tied to the plasma state of that specific step. Consequently, it becomes imperative to adjust the operating frequency fo (129) for every step, an action performed by a frequency tuning unit (125). The RF controller (132), associated with the RF power generator (114), provides a mechanism for this fine-tuning. This controller (132) is further linked to a system controller (116) that manages the overall operations of the process system (100). A sensor (130) is designed to ascertain a performance indicator of the RF generator (114). Using this indicator, the RF controller (132) adjusts the output frequency of the signal generator (128) to match the resonating frequency of the resonator (124), reflecting the real-time load of the process chamber (102).

In advanced process recipes for plasma etching chambers, transitions between process steps need to be swift and virtually instantaneous compared to the processing step durations. Thus, making mechanical adjustments to the capacitor's capacitance becomes inefficiently slow. Hence, frequency tuning emerges as the primary method to keep the resonator (124) in its resonating state.

Several techniques exist for adjusting the frequency within the RF power generator (114). One method involves measuring the power reflected from the processing chamber (102) at node (134) using the sensor (130). If the reflected power—relative to the input power from the DC-DC converter (118)—surpasses a set threshold, the RF controller (132) produces a new operating frequency, fo. To expedite the frequency's convergence to the desired resonating frequency, a PID control enabled by the RF controller (132) can be utilized. In alternative configurations, the phase difference at chosen nodes is evaluated against a reference value indicative of the resonator (124) in its resonating condition. A PID control loop, integrated with a PLL, serves to align the phase difference with this reference value. This PID control loop can be configured either in a digital or analog fashion.

Typically, bringing the resonator (124) to its resonating state via the PID control could take a duration from several milliseconds to several dozen millisecond. In scenarios where a rapid pulsing mechanism is in action, this latency is deemed excessive. Moreover, maximizing the PID control loop's speed can compromise the RF generator's stability. The current invention aims to address these challenges.

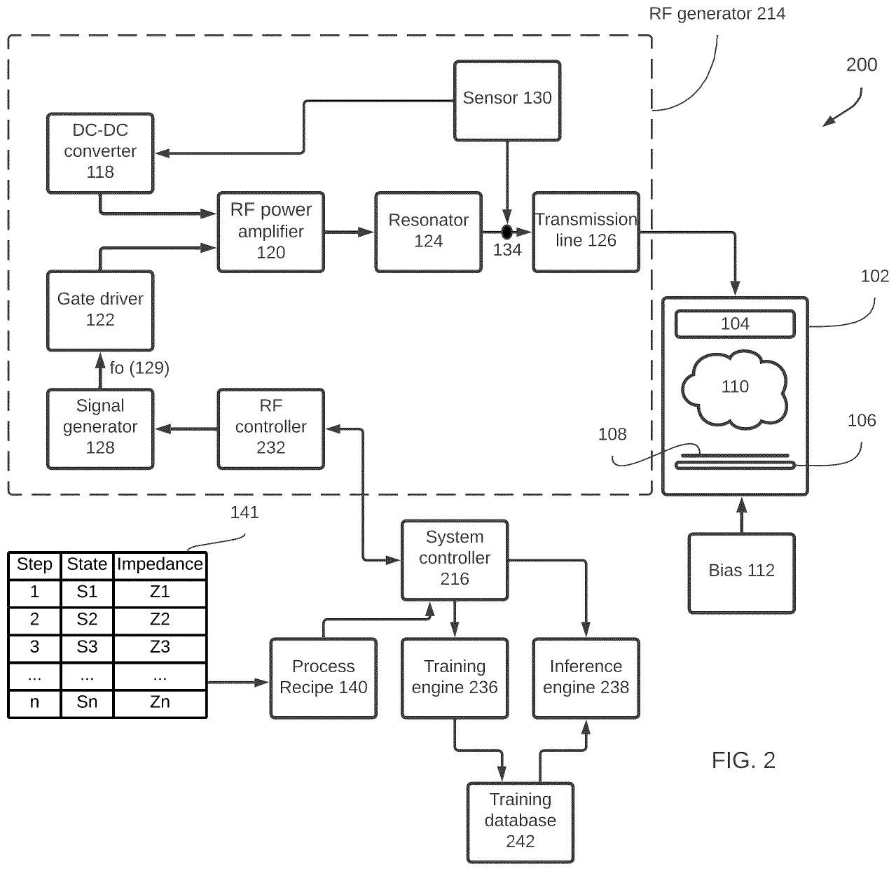

FIG. 2 depicts a functional diagram of an exemplary process system, labeled as system 200. This system incorporates a chamber (102), which includes a plasma source (104) and a chuck (106) designed to support substrate (108) throughout the process. The chuck (106) is connected to a bias unit (112), which supplies a voltage bias to speed up ions within the plasma (110). The RF power generator (214) is connected to chamber (102). The notable difference between RF generators (214) and (114) (from FIG. 1) is the way the operating frequency fo (129) is generated.

In the embodiment showcased in FIG. 2, the system controller directly provides fo (129) to the RF controller (232) in RF power generator (214). A signal generator (128) acquires fo from RF controller (232), aligning with the resonating frequency of resonator (124) without additional adjustments. The associated PID control loop with RF controller (232) is rendered redundant, allowing resonator (124) to reach its resonating state within microseconds or less, a significant reduction from the prior art.

The system controller (216) includes both a training engine (236) and an inference engine (238). In certain implementations, the training engine (236) is software-based and stored within the system controller (216). In others, it may be a combination of software, firmware, and hardware. This training engine (236) pre-determines resonating frequencies linked with each recipe state (from S1 to Sn) before process system (200) begins substrate (108) processing. This results in the creation of a training database (242), stored within system controller (216) or RF controller (232).

In one implementation, values of the performance indicator are measured across a predetermined frequency range. The resonating frequency can be decided based on measured data using an interpolating or an extrapolating algorithm. In another implementation, a neural network may be constructed and trained based on measured performance indicators as a function of the operating frequency. The resonating frequency can then be decided based on the neural network. When the neural network is employed, more factors affecting the resonating frequency can be incorporated.

The predetermined frequency range should adequately cover the resonating frequency. The frequency scanning should be applied to each of the plasma states stipulated by the process recipe.

When process system (200) initiates the substrate (108) processing, system controller (216) employs inference engine (238), referencing the training database (242) to determine the resonating frequency. This inference engine (238) could be software, firmware, hardware, or a combination. Once system controller (216) receives process recipe (140), it generates the relevant operating frequencies which are the resonating frequencies for the process steps, respectively. In one method, these frequencies are stored in RF controller (232), quickly relaying them to signal generator (128). For instance, these frequencies can be cached in SRAM and dispatched to signal generator (128) as the process step transition commences.

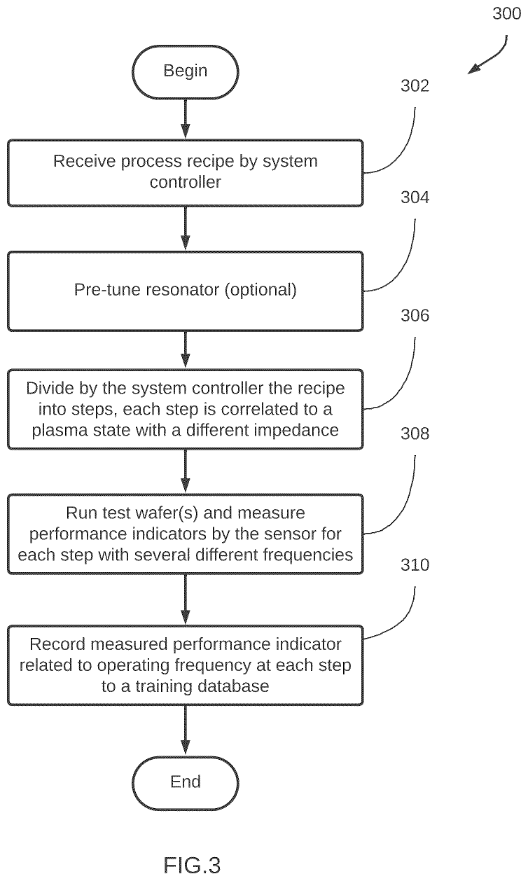

FIG. 3 portrays a training process, labeled as process 300, conducted by system controller (216) using training engine (236). The process begins with step 302, where system controller (216) receives process recipe (140). In one implementation, resonator (124) houses an adjustable capacitor, manipulated by applying a mechanical force, such as motorized rotation. At step 304, resonator (124) is preliminarily adjusted, setting the capacitor based on a predefined load impedance. In step 306, the process recipe is broken down into various steps (as detailed in table 141). Each step corresponds to a unique plasma state and impedance.

The resonating frequency for each state (S1 to Sn) is identified through a specific training regimen in step 308, which might include running the process recipe in system 200 with one or more test wafers. During each process step, the operating frequency's performance is gauged, for instance, by assessing the reflected power from chamber (200) via sensor (130) at resonator (124)'s output (134). Several operating frequencies for each step may be tested using the test wafer(s). These performance indicators, in relation to the operating frequency, are logged in training database (242) in step 310. System controller (216) then determines each plasma state's resonating frequency based on this training database.

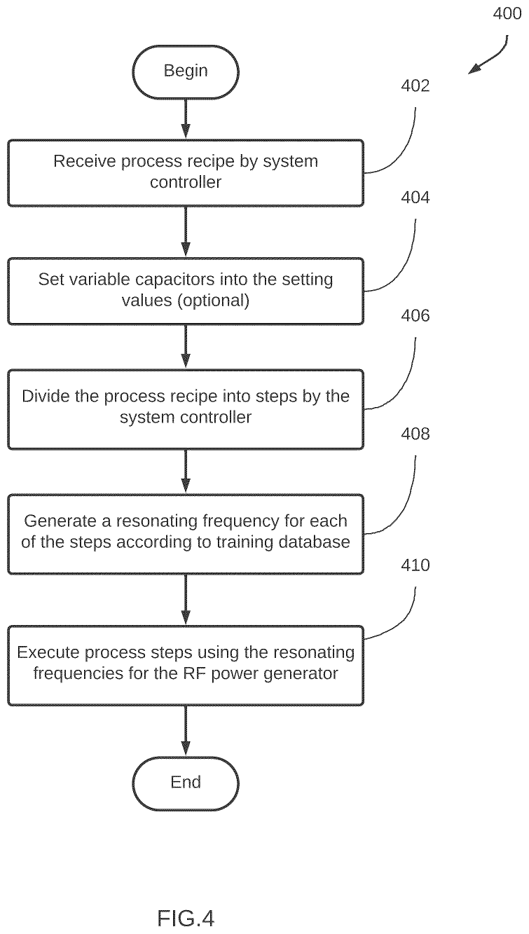

FIG. 4 depicts an exemplary inference process, labeled as process 400. During the fabrication of substrate (108), the resonating frequency for each step is deduced from the training database (242) contained within system controller (216). At step 402, the system controller (216) acquires the process recipe (140) meant for the substrate (108) production. If the resonator (124) has adjustable capacitors, their capacitances are tuned to preset values in step 404 (optional). These initial steps, 402 and 404, are vital as system (200) could be involved in performing varied process recipes tailored to different substrates in a conventional production setting.

At step 406, the process recipe is segmented into steps based on the insights from training database (242). Then, at step 408, the system controller (216) establishes the resonating frequencies for each step through inference engine (238). By step 410, the process steps are put into action, each utilizing its resonating frequency corresponding to its respective plasma state.

In one implementation, the resonating frequencies for each of the states are generated by the training engine and are stored in the training database. In such a case, the inference process can be simplified to fetch the stored resonating frequencies from the training database.

In another implementation, the resonating frequencies are generated by the inference engine according to measured data stored in the training database. The resonating frequencies can then be applied by either the system controller or the RF controller when the process recipe is received for substrate processing.

The occurrence for executing the training process (300) can also be flexible. It may be trained for each wafer, each lot, or a batch of lots. It can also be trained once a new process recipe is applied. The neural network version of the implementation will give more capability to include variables in the process system to predict the resonating frequency accurately at a specific time between preventive maintenance events. All such variations in implementations fall into the scope of the present inventive concept.

In a production environment, it's optional to evaluate performance indicators for every step or selected steps. These assessed performance indicators are systematically logged and overseen. To maintain process consistency, an SPC methodology can be applied to these performance indicators. The training event can then be triggered by evaluating trends presented based on SPC by the system controller.

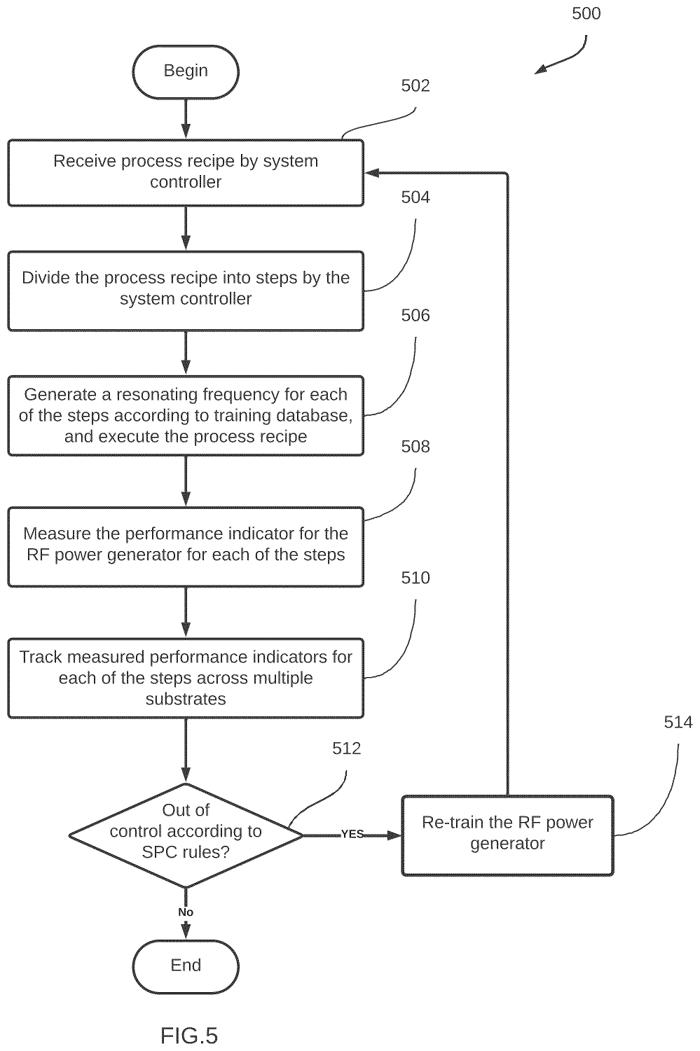

FIG. 5 demonstrates an illustrative production control process (500). This process (500) initiates with steps 502-506, mirroring the proceedings of process (400). What sets this apart is step 508, where performance indicators are gauged for every process step or selected steps. These indicators, gathered across multiple substrates, are logged, and consistently tracked. The SPC methodology is employed to scrutinize the step's stability. If, at step 512, a particular indicator deviates beyond preset parameters, step 514 is invoked, instigating a re-training phase for the RF power generator.

1. A process system, comprising:
a chamber designed to function within a vacuum environment;
an RF power generator coupled to a plasma source of the chamber, wherein said RF power generator further comprises a power amplifier, a resonator, and a signal generator; and
a system controller that governs the RF power generator, either in a training or inference mode, wherein in said training mode, the system controller identifies resonator's resonating frequencies for a plurality of plasma states stipulated by a process recipe and, in said inference mode, the system controller ensures that the resonator operates using the identified resonating frequencies throughout execution of the process recipe for each of the plurality of plasma states.

2. The system of claim 1, wherein said RF power generator further includes a sensor for measuring a performance indicator of RF power delivery.

3. The system of claim 2, wherein said performance indicator further includes a reflected power from the chamber to an output of the resonator.

4. The system of claim 2, wherein said system controller determines the resonating frequencies for said plurality of plasma states through measuring the performance indicator by operating the RF power generator at a set of predetermined frequencies in a predetermined range.

5. The system of claim 1, wherein a neural network is trained based on data collected in the training mode and the neutral network is employed to predict the resonating frequencies of the resonator for each of the plurality of the plasma states.

6. The system of claim 1, wherein said RF power generator further includes a DC-DC converter and a gate driver for the power amplifier.

7. The system of claim 1, wherein said resonator of said RF power generator matches the power amplifier's output impedance to a load impedance of the chamber, including transmission line effects.

8. The system of claim 7, wherein said impedance matching circuit further includes variable capacitors.

9. The system of claim 8, wherein capacitances of the variable capacitors are pre-tuned before the RF power generator enters into the training mode.

10. The system of claim 9, wherein said capacitances of the capacitor are unchanged when the RF power generator is operated in the training and inference modes.

11. The system of claim 1, wherein said resonator of said RF power generator does not include variable capacitors.

12. A method for delivering RF power to a chamber within a process system, comprising the steps of:
receiving a process recipe, which encompasses a multitude of steps, by a system controller of the process system;
correlating each of said steps by the system controller with a respective plasma state, wherein each plasma state is distinguished by a specific plasma impedance;
determining a resonating frequency for a resonator at each of said plasma states, wherein the resonator is affixed at one terminal to an output of an RF power amplifier and at another terminal to a chamber via a transmission line; and
executing all steps of the process recipe by the system controller by applying the determined resonating frequency corresponding to each step without additional frequency tuning.

13. The method of claim 12, wherein the step of determining resonating frequencies further comprises a step of gauging a performance indicator of RF power delivery utilizing a sensor.

14. The method of claim 13, wherein said performance indicator incorporates reflected power from the plasma chamber, measured at an output terminal of the resonator.

15. The method of claim 13, further comprising a step of evaluating the performance indicator while operating the RF power generator in the inference mode.

16. The method of claim 15, wherein the measured performance indicators for each of the plasma states during production events are monitored, and a retraining event is initiated if a trend of the performance indicator deviates from control limits in accordance with predetermined rules of SPC.

17. An RF power generator, comprising:
an RF power amplifier connected to a chamber via a resonator;
an RF controller, interfaced with a system controller of the chamber;
a signal generator, wherein its operating frequency is regulated by the RF controller;
a training mode, initiated by the system controller, designed to determine resonating frequencies for a plurality of plasma states as delineated by a process recipe; and
an inference mode, triggered by the system controller, purposed for operating the resonator at its predetermined resonating frequency for each of the plurality of the plasma states without additional frequency tuning.

18. The RF power generator of claim 17, wherein said resonator further includes an impedance matching circuit comprising capacitors with tunable capacitance.

19. The RF power generator of claim 18, wherein values of the capacitors are determined in a pre-tuning step and remain unchanged during operations in the training and inference modes.

20. The RF power generator of claim 17, wherein said RF controller further includes a training engine and an inference engine.
